(19) United States
(12) Patent Application Publication
(10) Pub. No.: US 2025/0337366 A1
(43) Pub. Date: Oct. 30, 2025

(54) AMPLIFICATION CIRCUIT

(71) Applicant: RichWave Technology Corp., Taipei City (TW)

(72) Inventors: Ching-Wen Hsu, Taipei City (TW); Chih-Sheng Chen, Taipei City (TW); Tien-Yun Peng, Taipei City (TW)

(73) Assignee: RichWave Technology Corp., Taipei City (TW)

(21) Appl. No.: 18/983,372

(22) Filed: Dec. 17, 2024

Related U.S. Application Data
(60) Provisional application No. 63/638,950, filed on Apr. 26, 2024.

(30) Foreign Application Priority Data
Dec. 6, 2024 (TW) 113147330

(51) Int. Cl. H03F 1/26; H03F 1/56; H03F 3/24; H03F 3/72

(52) U.S. Cl. CPC H03F 1/26; H03F 1/565; H03F 3/245; H03F 3/72; H03F 2200/451; H03F 2203/7233

(57) ABSTRACT

An amplification circuit includes a first signal terminal, a second signal terminal, a first path, and a second path. The first path is coupled between the first signal terminal and the second signal terminal. The second path is coupled to be in parallel with at least a portion of the first path. The first path includes an input matching network, a first amplifier, and a first switch unit. A first terminal of the input matching network is coupled to the first signal terminal. An input terminal of the first amplifier is coupled to a second terminal of the input matching network. A first terminal of the first switch unit is coupled to a second terminal of the input matching network, and a second terminal of the first switch unit is coupled to a first reference voltage terminal. When the second path is enabled, the first switch unit is turned on.

### CROSS REFERENCE TO RELATED APPLICATION

This application claims the benefit of U.S. Provisional Application No. 63/638,950, filed on Apr. 26, 2024, and the benefit of TW application Ser. No. 11/314,7330, filed on Dec. 6, 2024. The content of the applications are incorporated herein by reference.

### TECHNICAL FIELD

The disclosure is related to an amplification circuit, and more particularly, an amplification circuit capable of being operated in a plurality of modes with an improved noise figure and an accelerated transition to a steady state.

### BACKGROUND

As the development of electronic products, the demand for signal processing circuits is also increasing. When the received signal is not so strong, an amplifier may be used to amplify the signal. Conversely, when the received signal is strong enough, the amplifier may be bypass and the signal may be directed to a bypass path. When designing circuits, the noise figure (NF) is an important consideration. The noise figure may be related to the SNR (signal-to-noise ratio) of the input signal compared to that of the output signal. Generally, the lower the noise figure is, the better the performance of the circuit may be. Another important consideration in circuit design is the time required for the circuit to reach a steady state. It has been found that many solutions used to reduce the noise figure may lead to longer durations for the circuit to reach a steady state, which is unfavorable for circuit operation. Therefore, there is a need for a solution which may provide a desirable noise figure and an acceptable duration to reach a steady state.

### SUMMARY

An embodiment of the present disclosure provides an amplification circuit, which may include a first signal terminal, a second signal terminal, a first path, and a second path. The first path may be coupled between the first signal terminal and the second signal terminal. The second path may be coupled in parallel with at least a portion of the first path. The first path may include an input matching network, a first amplifier, and a first switch unit. The input matching network may include a first terminal and a second terminal, and the first terminal may be coupled to the first signal terminal. The first amplifier may include an input terminal and an output terminal, and the input terminal may be coupled to the second terminal of the input matching network. The first switch unit may include a first terminal and a second terminal, the first terminal may be coupled to the second terminal of the input matching network, and the second terminal may be coupled to a first reference voltage terminal. When the second path is enabled, the first switch unit may be turned on.

Another embodiment of the present invention provides an amplification circuit, which may include a first signal terminal, a second signal terminal, a third signal terminal, a first path, a second path, and a third path. The first path may be coupled between the first signal terminal and the second signal terminal. The second path may be coupled in parallel with at least a portion of the first path, and may be connected to a first node and a second node of the first path. The third path may be coupled between the first signal terminal and the third signal terminal. The first path may include a first amplifier, a first switch unit, and a second switch unit. An input terminal of the first amplifier may be coupled to the first signal terminal. A first terminal of the first switch unit may be coupled to the first signal terminal, and a second terminal of the first switch unit may be coupled to a first reference voltage terminal. The second switch unit may include a third switch, a fourth switch, and a fifth switch. A first terminal of the third switch may be coupled to an output terminal of the first amplifier, and a second terminal of the third switch may be coupled to a second reference voltage terminal. A first terminal of the fourth switch may be coupled to the output terminal of the first amplifier, and a second terminal of the fourth switch may be coupled to the second signal terminal. A first terminal of the fifth switch may be coupled to the node between the second terminal of the fourth switch and the second node, and a second terminal of the fifth switch may be coupled to a third reference voltage terminal. When the third path is enabled, the fifth switch may be turned on.

### BRIEF DESCRIPTION OF THE DRAWINGS

FIG. 1 schematically shows an amplification circuit according to an embodiment.

FIG. 2 schematically shows a switch unit according to an embodiment.

FIG. 3 schematically shows a first path according to an embodiment.

FIG. 4 schematically shows an amplification circuit according to another embodiment.

FIG. 5 schematically shows a switch unit according to various embodiments.

FIG. 6 schematically shows a matching network according to an embodiment.

FIG. 7 schematically shows an amplifier according to an embodiment.

FIG. 8 schematically shows an amplification circuit according to another embodiment.

FIG. 9 schematically shows an amplification circuit according to yet another embodiment.

### DETAILED DESCRIPTION

Below, exemplary embodiments will be described in detail with reference to accompanying drawings so as to be easily realized by a person having ordinary knowledge in the art. The inventive concept may be embodied in various forms without being limited to the exemplary embodiments set forth herein. Descriptions of well-known parts may be omitted for clarity, and like reference numerals refer to like elements throughout.

By referring to the following detailed description in conjunction with the accompanying drawings, the present invention may be well-understood. It should be noted that, for the ease of understanding by the reader and for the brevity of the drawings, only parts of the electronic device may be depicted, and specific elements in the figures may not be drawn to scale. Furthermore, the quantities and sizes of the elements in the figures may be merely illustrative and not intended to limit the scope of the present invention. In the drawings, elements marked with the same symbols may have the same or similar properties or functions in the context. It should be understood that features in one embodiment below may be replaced, reorganized, or combined with features from another embodiment without departing from the spirit of the present invention, so as to complete a further embodiment. Features in each embodiment may be used alone or in combination, as long as they do not contradict or conflict with the spirit of the invention.

In this text, when a component is mentioned as being coupled to another component, it may be directly or indirectly coupled through other components. The reference voltage terminal described herein may provide a substantially stable reference voltage. The reference voltage terminal described herein may be, but is not limited to, a ground terminal. A plurality of reference voltage terminals described herein may be the same reference voltage terminal or different reference voltage terminals. The switches described herein may be turned on or turned off. When the switch is turned on, the signal may pass through the switch, and when the switch is turned off, the signal may be blocked by the switch. The signal described herein may be a current signal and/or a voltage signal. The switches described herein may be implemented using transistors or other suitable electronic components. As an example, when the switch includes a field-effect transistor, a first terminal of the switch may correspond to one of the drain and the source, and a second terminal of the switch may correspond to the other one. The switch may be controlled through a control terminal, which may correspond to the gate. As another example, when a switch includes a bipolar transistor, a first terminal of the switch may correspond to one of the collector and the emitter, and a second terminal of the switch may correspond to the other. The switch may be controlled through a control terminal, which may correspond to the base. In this text, when a component is referred to as being optionally or selectively provided or configured, it means that the component may be provided or not as required, and both cases fall within the scope of embodiments.

In the following specification and claims, terms “comprise,” “include,” and “have” are open-ended terms and therefore should be interpreted as “including, but not limited to.” Therefore, when these terms are used, they specify the presence of corresponding features, such as regions, steps, operations, and/or components, but do not exclude the presence of other features.

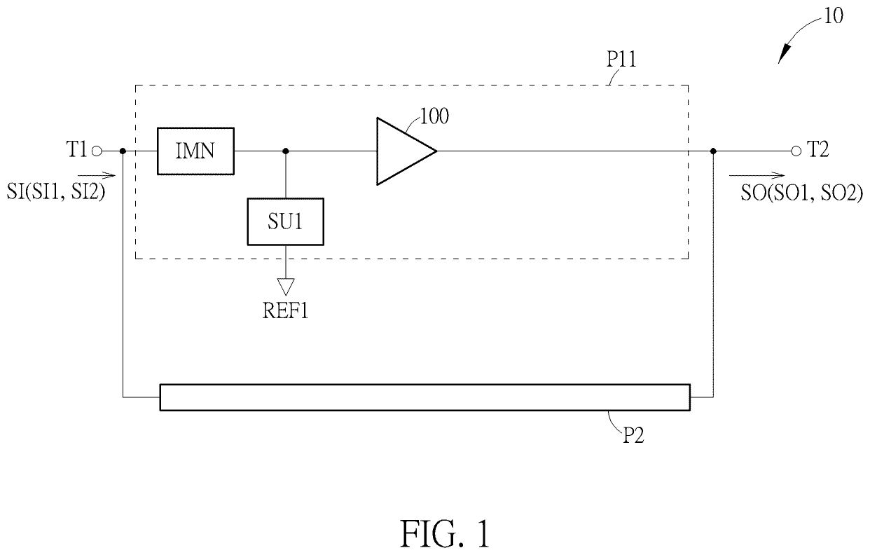

FIG. 1 schematically shows an amplification circuit 10 according to an embodiment. As shown, the amplification circuit 10 may include a first signal terminal T1, a second signal terminal T2, a first path P11, and a second path P2. The first signal terminal T1 may receive a radio frequency (RF) input signal SI (e.g., a first input signal SI1, a second input signal SI2). The second signal terminal T2 may output a radio frequency output signal SO corresponding to the radio frequency input signal SI (e.g., a first output signal SO1, a second output signal SO2).

In some embodiments, the first path P11 may be coupled between the first signal terminal T1 and the second signal terminal T2. The second path P2 may be coupled in parallel with at least a portion of the first path P1. Specifically, the first path P11 may include an input matching network IMN, a first amplifier 100, and a first switch unit SU1. The input matching network IMN may include a first terminal and a second terminal, the first terminal may be coupled to the first signal terminal T1, and the second terminal may be coupled to the first amplifier 100. The first amplifier 100 may include an input terminal and an output terminal, the input terminal may be coupled to the second terminal of the input matching network IMN, and the output terminal may, for example, be coupled to the second signal terminal T2 further through other components. The first switch unit SUI may include a first terminal and a second terminal, the first terminal may be coupled to the second terminal of the input matching network IMN, and the second terminal may be coupled to a reference voltage terminal REF1. As shown, the first terminal of the first switch unit SUI may be substantially coupled to a node between the input matching network IMN and the first amplifier 100.

In some embodiments, the first path P11 may be an amplification path. For example, in the case where the first signal terminal T1 receives the first input signal SI1, the first amplifier 100 may amplify the signal to generate an amplified signal, and the amplified signal (e.g., the first output signal SO1) may be output via the second signal terminal T2. The first path P11 may include more amplifiers, such as multi-stage amplifiers. For instance, the first amplifier 100 may include a low-noise amplifier (LNA), a power amplifier (PA), or other suitable amplifiers. The first amplifier 100 may include a plurality of transistors coupled in a cascode manner.

In some embodiments, the second path P2 may be a bypass path, which may be specifically implemented by using a metal conductive line. For example, in the case where the first signal terminal T1 receives a second input signal SI2, the second input signal SI2 may be transmitted via the second path P2 instead of the first path P11. For example, the second path P2 may not include an amplifier. However, the present invention is not limited thereto. In other embodiments, the second path P2 may function as an additional amplification path, which may provide a different magnification from the first path P11 for the input signal, and its details may be omitted herein.

In some embodiments, as shown, the amplification circuit 10 may be operated in at least one mode. For example, the amplification circuit 10 may be operated in a first mode, which may be an amplification mode. In this mode, the first path P11 may be enabled, and the RF signal received by the first signal terminal T1 (such as the first input signal SI1) may be transmitted via the first path P11 and an amplified RF signal (such as the first output signal SO1) may be output at the second signal terminal T2. Specifically, the first input signal SI1 received by the first signal terminal T1 may sequentially pass through the input matching network IMN and the first amplifier 100, and be further transmitted to the second signal terminal T2. In other words, in the first mode (e.g., the amplification mode), the first input signal SI1 may be amplified to generate the first output signal SO1. In this mode, the first switch unit SU1 may be turned off, so as to prevent the RF signal transmitted along the first path P11 from leaking to the reference voltage terminal REF1. The second path P2 may be disabled, so that the first input signal SI1 received by the first signal terminal T1 is substantially not transmitted through the second path P2.

In the first mode, the input matching network IMN of the first path P11 may provide a smaller first impedance for the first input signal SI1, and the components of the second path P2 (e.g., the bypass switch SWb described below) may provide a larger second impedance for the first input signal SI1. In some embodiments, the second impedance may be approximately infinite.

In some embodiments, as shown, the amplification circuit 10 may also be operated in a second mode, such as a bypass mode. In this mode, the second path P2 may be enabled, and the RF signal received by the first signal terminal T1 (e.g., the second input signal SI2) may be transmitted through the second path P2 and an amplified RF signal (e.g., the second output signal SO2) may be output at the second signal terminal T2. The amplitude of the second output signal SO2 may be substantially equal to the amplitude of the second input signal SI2. In other words, in the second mode (e.g., the bypass mode), the second input signal SI2 may not be amplified, and the output signal SO2 is generated. In this mode, the first switch unit SUI may be turned on, so as to redirect the RF signal leaked to the first path P11 to the reference voltage terminal REF1. The first path P11 may be disabled, so that the second input signal SI2 received by the first signal terminal T1 is substantially not transmitted through the first path P11.

In the second mode, the input matching network IMN and the first switch unit SUI of the first path P11 may provide a larger third impedance for the second input signal SI2. The components of the second path P2 (e.g., the bypass switch SWb described below) may provide a smaller fourth impedance for the second input signal SI2. In some embodiments, the third impedance may be greater than the fourth impedance.

In some embodiments, the second path P2 may be coupled in parallel with the first path P11 between the first signal terminal T1 and the second signal terminal T2. However, the present invention is not limited thereto. In other embodiments, the second path P2 may be coupled in parallel with only a portion of the first path P1. For example, the second path P2 may be coupled in parallel with the first switch unit SU1 and the first amplifier 100 of the first path P1. In other words, the second path P2 may be coupled between the first terminal of the first switch unit SUI and the output terminal of the first amplifier 100.

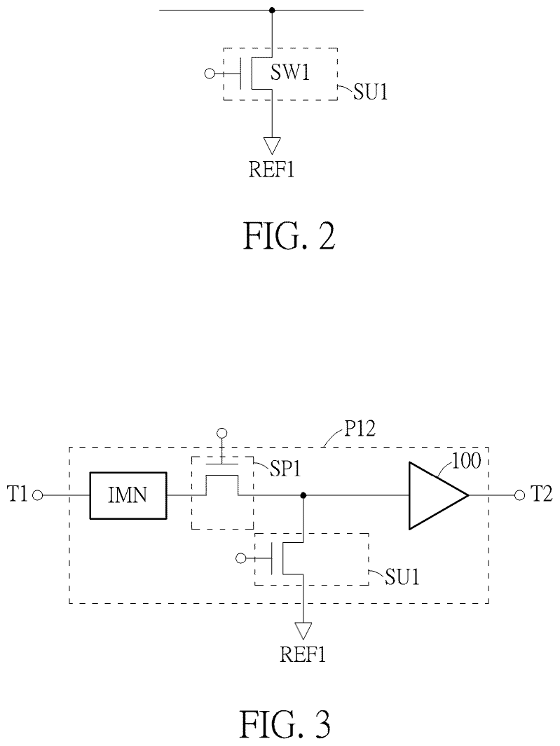

FIG. 2 schematically shows a switch unit SUI according to an embodiment. As shown, the first switch unit SUI may include a first switch SW1, the first terminal of the first switch SW1 may be coupled to the second terminal of the input matching network IMN, and the second terminal of the first switch SW1 may be coupled to the first reference voltage terminal REF1.

FIG. 3 schematically shows a first path P12 according to an embodiment. The first path P12 may be similar to the first path P11 in FIG. 1 but further includes an additional switch unit SP1. As shown, the switch unit SP1 may include a first terminal and a second terminal, the first terminal may be coupled to the second terminal of the input matching network IMN, and the second terminal may be coupled to the input of the first amplifier 100. In other words, the switch unit SP1 may be coupled in series between the input matching network IMN and the first amplifier 100. When the amplification circuit operates in the first mode, the first path P12 may be enabled, and in this case the switch unit SP1 may be turned on. When the amplification circuit operates in the second mode, the first path P12 may be disabled, and in this case, the switch unit SP1 may be turned off. Thus, the dynamic error vector magnitude (DEVM) of the transistors in the amplifier 100 may be reduced, and the performance may be improved. For example, the switch unit SP1 may include a second switch (not shown).

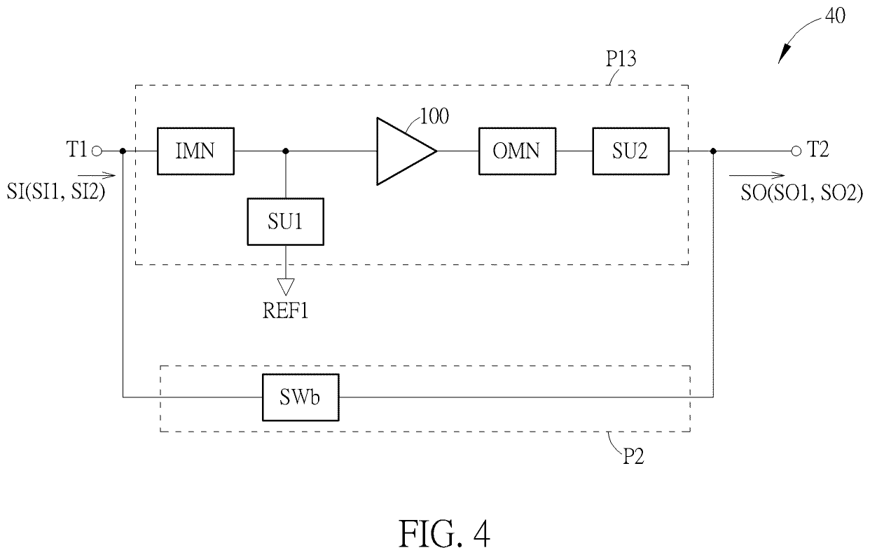

FIG. 4 schematically shows an amplification circuit 40. The amplification circuit 40 may be similar to the amplification circuit 10, and differences may be described as follows. As shown, the first path P13 of the amplification circuit 40 may further include an output matching network OMN and a second switch unit SU2. The output matching network OMN may include a first terminal and a second terminal, and the first terminal may be coupled to the output terminal of the first amplifier 100. The second switch unit SU2 may be coupled between the first amplifier 100 the second signal terminal T2. Further, the second switch unit SU2 may include a first terminal and a second terminal, the first terminal may be coupled to the second terminal of the output matching network OMN, and the second terminal may be coupled to the second signal terminal T2. In other words, the first terminal of the second switch unit SU2 may be coupled, through the output matching network OMN, to the output terminal of the first amplifier 100. In some embodiments, optionally, as shown, the second path P2 of the amplification circuit 40 may further include a bypass switch SWb. The bypass switch SWb may include a first terminal and a second terminal, the first terminal may be coupled to the first signal terminal T1, and the second terminal may be coupled to the second signal terminal T2. In other words, the bypass switch SWb may be coupled in series in the second path P2.

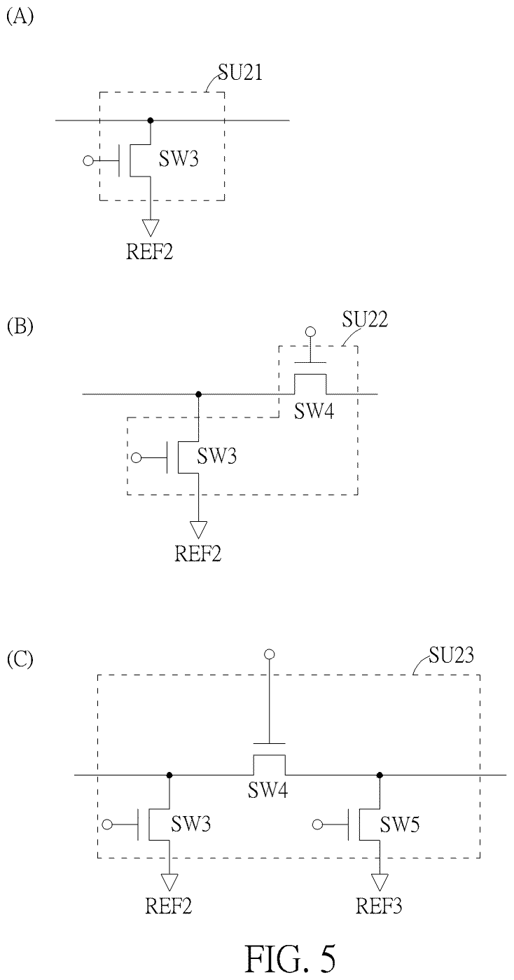

FIG. 5 schematically shows the second switch unit SU2 according to various embodiments. FIGS. 5(A), 5(B), and 5(C) show various second switch units SU21, SU22, and SU23 as examples.

As shown in FIG. 5(A), the second switch unit SU21 may include a switch SW3. The switch SW3 may include a first terminal and a second terminal, the first terminal may be coupled to the output terminal of the first amplifier 100, and the second terminal may be coupled to the reference voltage terminal REF2. Furthermore, as shown in FIG. 5(B), the second switch unit SU22 may further include a switch SW4. The switch SW4 may include a first terminal and a second terminal, the first terminal may be coupled to the output terminal of the first amplifier 100, and the second terminal may be coupled to the second signal terminal T2. In other words, the first terminal of the switch SW4 and the first terminal of the switch SW3 may be coupled together to the output terminal of the first amplifier 100. Moreover, as shown in FIG. 5(C), the second switch unit SU23 may also include a switch SW5. The switch SW5 may include a first terminal and a second terminal, the first terminal may be coupled to the second terminal of the switch SW4, and the second terminal may be coupled to the reference voltage terminal REF3. In FIG. 5(C), the switches SW3, SW4, and SW5 included in the second switch unit SU23 may form a x-type structure. In some embodiments, each of the above switches SW1 to SW5 may be implemented using at least one transistor, and the transistor may include a body terminal (also referred to as a bulk terminal) that may be contacted or tied. In other words, the body terminal of the transistor may be coupled to a predetermined voltage terminal or other components to maintain at a predetermined voltage level.

In at least one of the aforementioned embodiments, the first path P11, P13 may each include an input matching network IMN and/or an output matching network OMN, which may respectively be used to adjust the input and output impedance of the first amplifier 100, optimizing the power transmission of the first amplifier 100, improving power delivery, and enhancing the performance and efficiency of the amplifier.

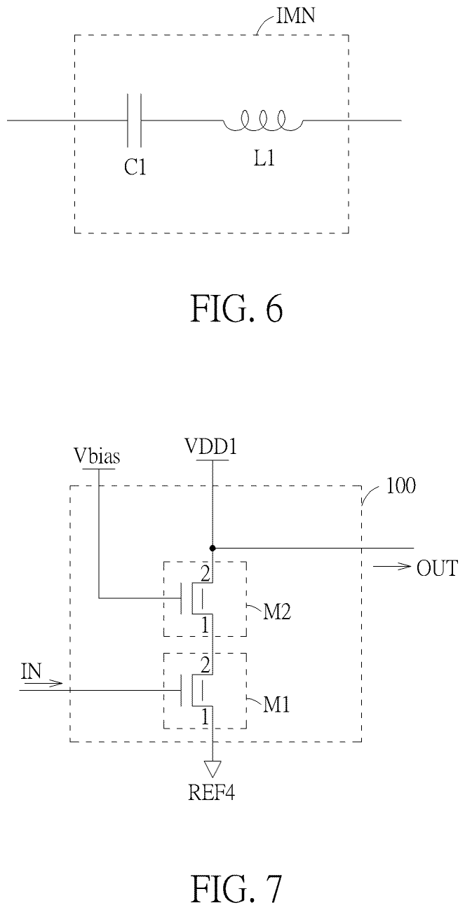

FIG. 6 schematically shows a matching network, such as the input matching network IMN, according to one embodiment. For example, the input matching network IMN may include a capacitor C1 and an inductor L1 coupled in series. The capacitor C1 may include a first terminal and a second terminal, and the first terminal may be coupled to the first terminal of the input matching network IMN. Thus, the first terminal of the capacitor C1 may be coupled to the first signal terminal T1. The inductor L1 may include a first terminal and a second terminal, the first terminal of the inductor L1 may be coupled to the second terminal of the capacitor C1, and the second terminal of the inductor L1 may be coupled to the second terminal of the input matching network IMN. Therefore, the second terminal of the inductor L1 may be coupled to the first amplifier 100. However, the present invention is not limited thereto. In other embodiments, the capacitor C1 and inductor L1 may be coupled in parallel, or the input matching network IMN may include more capacitors and/or inductors. In other embodiments, the input matching network IMN may be omitted.

FIG. 7 schematically shows an amplifier (e.g., the first amplifier 100) according to an embodiment. For example, the first amplifier 100 may include a first transistor M1. The first transistor M1 may include a first terminal, a second terminal, and a control terminal. The first terminal may be coupled to the reference voltage terminal REF4, and the control terminal may be coupled to the input terminal of the first amplifier 100 (e.g., the terminal IN as shown), so as to be coupled to the input matching network IMN. The first amplifier 100 may also include a second transistor M2. The second transistor M2 may include a first terminal, a second terminal, and a control terminal. The first terminal of the second transistor M2 may be coupled to the second terminal of the first transistor M1, the second terminal of the second transistor M2 may be coupled to a system voltage terminal VDD1, and the control terminal of the second transistor M2 may be coupled to a bias voltage terminal Vbias. In other words, the second transistor M2 and the first transistor M1 may be coupled in a cascode arrangement. For example, the bias voltage terminal Vbias may provide a bias signal for enabling or disabling the second transistor M2. Furthermore, the second terminal of the second transistor M2 may be further coupled to the output terminal of the first amplifier 100 (e.g., the terminal OUT as shown). However, the present invention is not limited thereto. In other embodiments, the second transistor M2 may be omitted.

In some embodiments, the transistors M1 and M2 may be manufactured using SOI (Silicon-on-Insulator) technology. For example, the first terminal of the transistor M1 or M2 may be one the source and the drain, and the second terminal may be the other. The control terminal may be the gate. Furthermore, the first transistor M1 may also include a floating body terminal. The second transistor M2 may also include a body terminal, which may be either contacted or floating. For example, a floating body terminal means that it may not have a predetermined voltage. A contacted body terminal may be coupled to a predetermined voltage terminal to maintain at predetermined voltage level.

In some embodiments, a transistor with a floating body terminal may provide a lower noise figure (NF). However, due to the instability of the voltage at the body, it may require a longer period to complete a state transition. For example, when the operating state of the first amplifier 100 changes, a transistor with a floating body terminal may take a longer time to reach a steady state, which may result in an undesirable transient response. In some embodiments, a transistor with a contacted body terminal may provide an improved transient response, i.e., it may take less time to reach a steady state. However, the contacted body terminal may come along with a higher noise figure (NF). For instance, in an embodiment, the first transistor M1 may be configured with a floating body terminal, the second transistor M2 may be configured with a contacted body terminal, and this configuration may advantageously trade off the noise figure (NF) and the transient response.

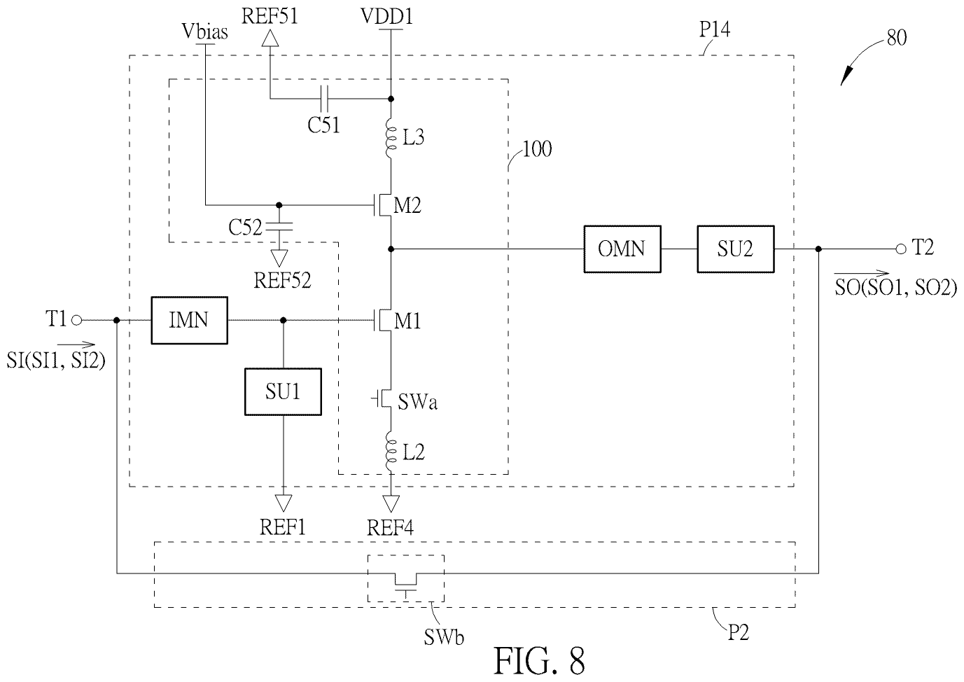

FIG. 8 schematically shows an amplification circuit 80 according to another embodiment. The amplification circuit 80 may be similar to the amplification circuit 10 or the amplification circuit 40, and differences may be described as follows. As shown, in the first path P14 of the amplification circuit 80, the first amplifier 100 may further include an auxiliary switch SWa. The auxiliary switch SWa may include a first terminal and a second terminal, the first terminal of the auxiliary switch SWa may be coupled to the reference voltage terminal REF4, and the second terminal of the auxiliary switch SWa may be coupled to the first terminal of the first transistor M1. The auxiliary switch SWa may be configured to improve the operation of the first amplifier 100. Specifically, when the first amplifier 100 is activated, the auxiliary switch SWa may be turned on, and when the first amplifier 100 is deactivated, the auxiliary switch SWa may be turned off, so as to provide an enhanced isolation between various paths.

In some embodiments, as shown, the first amplifier 100 may further include an inductor L2, an inductor L3, a capacitor C51, and/or a capacitor C52. The inductor L2 may be coupled between the auxiliary switch SWa and the reference voltage terminal REF4. The inductor L3 may be coupled between the second terminal of the second transistor M2 and the system voltage terminal VDD1. One terminal of capacitor C51 may be coupled to the reference voltage terminal REF51, and the other terminal may be coupled to inductor L3. One terminal of capacitor C52 may be coupled to the control terminal of the second transistor M2, and the other terminal may be coupled to the reference voltage terminal REF52.

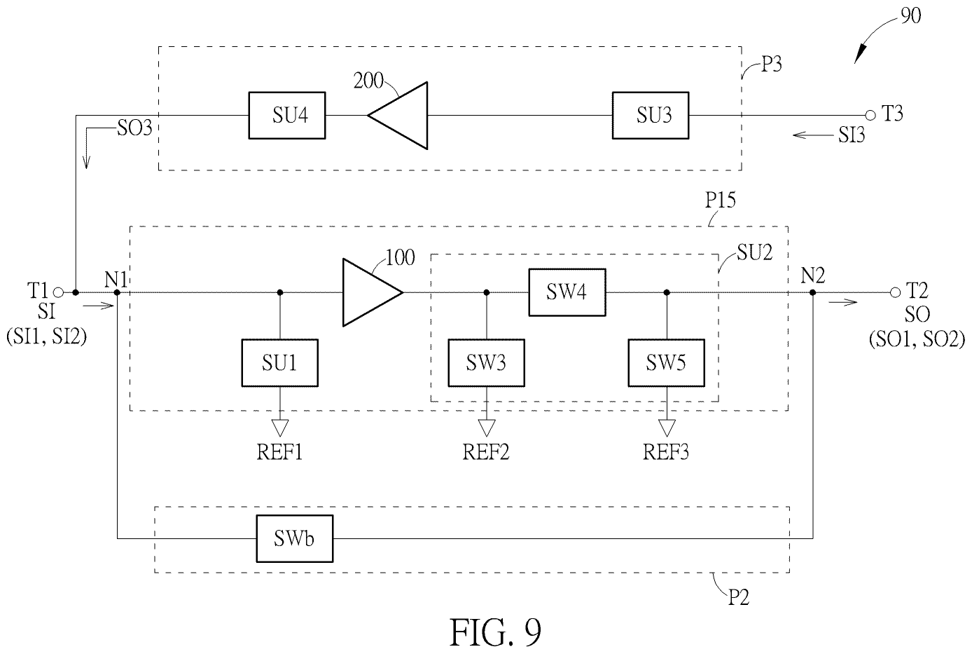

FIG. 9 schematically shows an amplification circuit 90 according to another embodiment. The amplification circuit 90 may be similar to amplification circuit 10 or 40, and differences may be described as follows. As shown, the second path P2 may be coupled in parallel with at least a portion of the first path P15. For example, the second path P2 may be coupled to the first path P15 at a first node NI and a second node N2. The second switch unit SU2 of the first path P15 may include switches SW3, SW4, and SW5, as the second switch unit SU23 shown in FIG. 5(C). However, this is merely an example, and the second switch unit SU2 may also be implemented as what shown in FIG. 5(A) or FIG. 5(B).

The amplification circuit 90 may further include a third path P3. The third path P3 may be coupled between the first signal terminal T1 and a third signal terminal T3. The third path P3 may include a third switch unit SU3, a second amplifier 200, and a fourth switch unit SU4. The third switch unit SU3 may include a first terminal and a second terminal, and the first terminal of the third switch unit SU3 may be coupled to the third signal terminal T3. The second amplifier 200 may include an input terminal and an output terminal, and the input terminal of the second amplifier 200 may be coupled to the second terminal of the third switch unit SU3. The fourth switch unit SU4 may include a first terminal and a second terminal, the first terminal of the fourth switch unit SU4 may be coupled to the output terminal of the second amplifier 200, and the second terminal of the fourth switch unit SU4 may be coupled to the first signal terminal T1. For example, in the third path P3, a signal may be transmitted from the third signal terminal T3 to the first signal terminal T1. For example, the signal SI3 may be transmitted from the third signal terminal T3 through the third path P3 and processed to generate a signal SO3 at the first signal terminal T1.

In some embodiments, the first signal terminal T1 may be coupled to an antenna, and the second amplifier 200 may be a power amplifier. The input matching network IMN and the output matching network OMN may be optionally provided. In other words, one or both of the input matching network IMN and the output matching network OMN may be provided as required. Alternatively, as shown, the input matching network IMN and the output matching network OMN may be both omitted.

In some embodiments, the specific implementations of the third switch unit SU3 and/or the fourth switch unit SU4 may be similar to the switch unit SP1 and/or the second switch unit SU2, and further details may not be repeat herein. The amplification circuit 90 may be operated in at least one mode, and various operating modes may be described below with reference to FIGS. 3 and 9, and some components, such as the switch unit SP1, may be omitted in FIG. 9.

The amplification circuit 90 may be operated in a first mode, such as a reception-low noise amplification mode (RX-LNA mode). In this mode, the first path P15 may be enabled, the second path P2 may be disabled, and the third path P3 may be disabled. A signal may be transmitted and processed through the first path P15. The signal may be input from the first signal terminal T1 and output from the second signal terminal T2. In this case, the first switch unit SUI of the first path P15 may be turned off. Furthermore, in the second switch unit SU2, the third switch SW3 may be turned off, the fourth switch SW4 may be turned on, and the fifth switch SW5 may be turned off. The bypass switch SWb of the second path P2 may be turned off. The third switch unit SU3 of the third path P3 may be turned off, and the fourth switch unit SU4 may be turned off.

The amplification circuit 90 may also be operated in a second mode, such as a bypass mode. In this mode, the first path P15 may be disabled, the second path P2 may be enabled, and the third path P3 may be disabled. A signal may be transmitted and processed through the second path P2. The signal may be input from the first signal terminal T1 and output from the second signal terminal T2. In this case, the first switch unit SUI of the first path P15 may be turned on, so as to redirect the unexpected signal leaked to the first path P15 to the reference voltage terminal. Furthermore, in the second switch unit SU2, the third switch SW3 may be turned on, the fourth switch SW4 may be turned off, and the fifth switch SW5 may be turned off. The bypass switch SWb of the second path P2 may be turned on. The third switch unit SU3 and the fourth switch unit SU4 of the third path P3 may be turned off.

The amplification circuit 90 may also operate in a third mode, such as a transmission-power amplification mode (TX-PA mode). In this mode, the first path P15 may be disabled, the second path P2 may be disabled, and the third path P3 may be enabled. A signal may be transmitted and processed through the third path P3, and the signal may be input from the third signal terminal T3 and output from the first signal terminal T1. In this case, the first switch unit SUI of the first path P15 may be turned on. Furthermore, in the second switch unit SU2, the third switch SW3 may be turned on, the fourth switch SW4 may be turned off or on, and the fifth switch SW5 may be turned on. The bypass switch SWb of the second path P2 may be turned off. The third switch unit SU3 and the fourth switch unit SU4 of the third path P3 may be turned on.

In some embodiments, the aforementioned at least one amplification circuit may achieve a desirable noise figure and an improved transient response. For example, an amplification circuit may be used to provide improved isolation between various paths. By employing a transistor with a floating body terminal, a lower noise figure may be achieved. Therefore, the configuration may reduce the noise figure and improve the operational speed and accuracy of the amplification circuit.

It should be noted that directional terms such as “up,” “down,” “left,” and “right” used in this document are only for illustrative purposes to describe the structure or method, and are not intended to limit the disclosure. The same terms in different descriptions or figures may have different meanings. In this document, some features, components, structures, materials, configurations, etc., may be illustratively described in an embodiment, but the disclosure is not limited to that embodiment. For example, components described in an embodiment may be omitted from that embodiment or applied to another embodiment.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An amplification circuit, comprising:
a first signal terminal;
a second signal terminal;
a first path coupled between the first signal terminal and the second signal terminal; and
a second path coupled in parallel with at least a portion of the first path;
wherein the first path comprises:
an input matching network, comprising a first terminal and a second terminal, the first terminal of the input matching network being coupled to the first signal terminal;
a first amplifier, comprising an input terminal and an output terminal, the input terminal of the first amplifier being coupled to the second terminal of the input matching network; and
a first switch unit, comprising a first terminal and a second terminal, the first terminal of the first switch unit being coupled to the second terminal of the input matching network, the second terminal of the first switch unit being coupled to a first reference voltage terminal; and
wherein when the second path is enabled, the first switch unit is turned on.

2. The amplification circuit of claim 1, wherein the first switch unit further comprises a first switch, wherein a first terminal of the first switch is coupled to the second terminal of the input matching network, and a second terminal of the first switch is coupled to the first reference voltage terminal.

3. The amplification circuit of claim 2, wherein the first path further comprises an additional switch unit, wherein a first terminal of the additional switch unit is coupled to the second terminal of the input matching network, and a second terminal of the additional switch unit is coupled to the input terminal of the first amplifier.

4. The amplification circuit of claim 1, wherein the first path further comprises a second switch unit, wherein:
the second switch unit comprises a first terminal and a second terminal, wherein the first terminal of the second switch unit is coupled to an output terminal of the first amplifier, and the second terminal of the second switch unit is coupled to the second signal terminal.

5. The amplification circuit of claim 4, wherein the second switch unit further comprises a third switch, a first terminal of the third switch is coupled to the output terminal of the first amplifier, and a second terminal of the third switch is coupled to a second reference voltage terminal.

6. The amplification circuit of claim 5, wherein the second switch unit further comprises a fourth switch, a first terminal of the fourth switch is coupled to the output terminal of the first amplifier, and a second terminal of the fourth switch is coupled to the second signal terminal.

7. The amplification circuit of claim 6, wherein the second switch unit further comprises a fifth switch, a first terminal of the fifth switch is coupled to the second terminal of the fourth switch, and a second terminal of the fifth switch is coupled to a third reference voltage terminal.

8. The amplification circuit of claim 4, wherein the first path further comprises an output matching network, wherein:
the output matching network comprises a first terminal and a second terminal, wherein the first terminal of the output matching network is coupled to the output terminal of the first amplifier, and the second terminal of the output matching network is coupled to the first terminal of the second switch unit.

9. The amplification circuit of claim 1, wherein the first amplifier further comprises a first transistor, wherein:
the first transistor comprises a first terminal, a second terminal, and a control terminal, wherein the first terminal of the first transistor is coupled to a fourth reference voltage terminal, and the control terminal of the first transistor is coupled to the input terminal of the first amplifier.

10. The amplification circuit of claim 9, wherein the first transistor further comprises a body terminal, and the body terminal of the first transistor is floating.

11. The amplification circuit of claim 9, wherein the first amplifier further comprises a second transistor, wherein:
the second transistor comprises a first terminal, a second terminal, and a control terminal, the first terminal of the second transistor is coupled to the second terminal of the first transistor, the second terminal of the second transistor is coupled to a system voltage terminal, and the control terminal of the second transistor is coupled to a bias voltage terminal.

12. The amplification circuit of claim 11, wherein the second transistor further comprises a body terminal, and the body terminal of the second transistor is contacted or floating.

13. The amplification circuit of claim 7, wherein the second path comprises a bypass switch, the bypass switch comprises a first terminal and a second terminal, the first terminal of the bypass switch is coupled to the first signal terminal, and the second terminal of the bypass switch is coupled to the second signal terminal.

14. The amplification circuit of claim 13, wherein when the amplification circuit is operated in a first mode, the first path is enabled, and the second path is disabled, wherein:
the first switch unit is turned off, the bypass switch is turned off, and the first signal terminal receives a first radio frequency signal; and
the input matching network provides a first impedance for the first radio frequency signal, the bypass switch provides a second impedance for the first radio frequency signal, and the first impedance is lower than the second impedance.

15. The amplification circuit of claim 13, wherein when the amplification circuit is operated in a second mode, the first path is disabled, and the second path is enabled, wherein:
the first switch unit is turned on, the bypass switch is turned on, and the first signal terminal receives a second radio frequency signal; and
the input matching network and the first switch unit provide a third impedance for the second radio frequency signal, the bypass switch provides a fourth impedance for the second radio frequency signal, and the third impedance is higher than the fourth impedance.

16. The amplification circuit of claim 14, wherein when the amplification circuit is operated in the first mode, in the second switch unit, the third switch is turned off, the fourth switch is turned on, and the fifth switch is turned off.

17. The amplification circuit of claim 15, wherein when the amplification circuit is operated in the second mode, in the second switch unit, the third switch is turned on, the fourth switch is turned off, and the fifth switch is turned off.

18. The amplification circuit of claim 7, further comprising a third path coupled between the first signal terminal and a third signal terminal, wherein the third path comprises:
a third switch unit comprising a first terminal and a second terminal, wherein the first terminal of the third switch unit is coupled to the third signal terminal;
a second amplifier comprising an input terminal and an output terminal, wherein the input terminal of the second amplifier is coupled to the second terminal of the third switch unit; and
a fourth switch unit comprising a first terminal and a second terminal, wherein the first terminal of the fourth switch unit is coupled to the output terminal of the second amplifier, and the second terminal of the fourth switch unit is coupled to the first signal terminal;
wherein when the amplification circuit is operated in a third mode, the third path is enabled, and the first path and the second path are disabled,
wherein the third switch unit is turned on, the fourth switch unit is turned on, and
wherein in the second switch unit, the fifth switch is turned on.

19. The amplification circuit of claim 7, wherein each of the third switch, the fourth switch, and the fifth switch is formed by using at least one transistor, the at least one transistor comprises a body terminal, and the body terminal is contacted.

20. The amplification circuit of claim 11, wherein the first amplifier further comprises an auxiliary switch, wherein
the auxiliary switch comprises a first terminal and a second terminal, the first terminal of the auxiliary switch is coupled to the fourth reference voltage terminal, and the second terminal of the auxiliary switch is coupled to the first terminal of the first transistor.

21. An amplification circuit, comprising:
a first signal terminal;
a second signal terminal;
a third signal terminal;
a first path coupled between the first signal terminal and the second signal terminal;
a second path coupled in parallel with at least a portion of the first path, and coupled to a first node and a second node of the first path; and
a third path coupled between the first signal terminal and the third signal terminal;
wherein the first path comprises:
a first amplifier, comprising an input terminal and an output terminal, wherein the input terminal of the first amplifier is coupled to the first signal terminal;
a first switch unit, comprising a first terminal and a second terminal, wherein the first terminal of the first switch unit is coupled to the first signal terminal, and the second terminal of the first switch unit is coupled to a first reference voltage terminal;
a second switch unit, comprising a third switch, a fourth switch, and a fifth switch, wherein
a first terminal of the third switch is coupled to the output terminal of the first amplifier, a second terminal of the third switch is coupled to a second reference voltage terminal;
a first terminal of the fourth switch is coupled to the output terminal of the first amplifier, and a second terminal of the fourth switch is coupled to the second signal terminal;
a first terminal of the fifth switch is coupled to a node between the second terminal of the fourth switch and the second node, and a second terminal of the fifth switch is coupled to a third reference voltage terminal;
wherein when the third path is enabled, the fifth switch is turned on.
